(19) United States
(12) Patent Application Publication
(10) Pub. No.: US 2008/0023704 A1
(43) Pub. Date: Jan. 31, 2008

(54) Display Device and Fabrication Method Thereof

(76) Inventors: TAKESHI NODA, Mobara (JP); Takahiro Kamo, Mobara (JP); Eiji Oue, Mobara (JP); Mutsuko Hatano, Kokubunji (JP); Takeshi Sato, Kokubunji (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/782,701

(22) Filed: Jul. 25, 2007

(30) Foreign Application Priority Data
Jul. 26, 2006 (JP) 2006-202712

(51) Int. Cl. H01L 29/04; H01L 21/00

(52) U.S. Cl. 257/72; 438/22; 257/E29.003; 257/E21.412

(57) ABSTRACT

The present invention obtains a system-in-panel display device using a high-performance thin film transistor by suppressing aggregation of a molten semiconductor at the time of allowing strip-like pseudo-single crystal to grow continuously with a direction control by radiating beams of continuous oscillation laser to a semiconductor film made of silicon while scanning. A display device includes a silicon nitride film formed on the insulation substrate, a silicon oxide film formed on the silicon nitride film, a semiconductor film formed on the silicon oxide film, and a thin film transistor which uses the semiconductor film. Here, the silicon oxide film is constituted of a first silicon oxide film formed using SiH₄ and N₂O as raw material gases and a second silicon oxide film formed using a TEOS gas as a raw material gas, and the semiconductor film is made of pseudo-single crystal having strip-like grains.

The present application claims priority from Japanese applications JP2006-202712 filed on Jul. 26, 2006, the content of which is hereby incorporated by reference into this application.

### BACKGROUND OF THE INVENTION

The present invention relates to a display device and a fabrication method thereof, and more particularly to a display device and a fabrication method which are suitable for the manufacture of an active-matrix flat-panel display device.

In an active-matrix flat-panel display device such as a liquid crystal display device or an organic EL display device, on a main surface of an insulation substrate made of glass or the like which arranges pixels two-dimensionally in a matrix array, a drive circuit which uses thin film transistors (TFT) for turning on and off the pixels and an auxiliary circuit are mounted thus realizing a high-definition and a high-speed display.

In fabricating a system-in panel which mounts a peripheral circuit including a drive circuit for display together with a pixel circuit of a display region (pixel region) on an insulation substrate preferably formed of a glass substrate, it is advantageous to use a higher functional silicon layer for forming a channel of a thin film transistor which is an active layer. As one of crystallization methods for obtaining a high-functional silicon layer, there has been known a method which uses a continuous oscillation laser thus continuously achieving a growth of crystals with a direction control. Due to such a method, it is possible to obtain pseudo-single crystals having strip-like crystal particles.

Patent document 1: JP-A-2006-19466

### SUMMARY OF THE INVENTION

However, in the above-mentioned method which uses the continuous oscillation laser, a melting time of silicon is long and hence, due to a surface tension of molten silicon, silicon is aggregated at the frequency of approximately 1.4 pieces/cm² empirically. When such aggregation occurs, portions where a silicon layer is not formed are present on the insulation substrate and hence, the thin film transistor becomes inoperable thus giving rise to lowering of a fabrication yield rate.

In forming a top-gate type thin film transistor, as a background film which is brought into contact with the silicon layer, a silicon oxide film is used. In forming the silicon oxide film, two kinds of silicon oxide films, that is, a silicon oxide film which is formed using SiH₄ and N₂O gas as raw material gases using a plasma CVD method (hereinafter, referred to as silicon oxide film A) and a silicon oxide film which is formed using TEOS as a raw material gas (hereinafter, referred to as silicon oxide film B) are considered. When a control of aggregation is emphasized, it is preferable to use the silicon oxide film A, while when properties (carrier mobility, ON current and the like) of the thin film transistor are emphasized, it is preferable to use the silicon oxide film B.

However, it is necessary for the silicon oxide film which constitutes the background to ensure a certain film thickness and hence, the use of only one of the silicon oxide film A and the silicon oxide film B is difficult to obtain the thin film transistor having desired properties while suppressing aggregation. Here, as a method for suppressing the generation of aggregation of a molten silicon film by reducing the influence of a surface tension by enhancing the wettability of the silicon film with a background film (silicon oxide film), a method which uses a film exhibiting small polarizability to a silicon oxide film as a background film is disclosed in patent document 1.

It is an object of the present invention to provide a system-in-panel display device which uses a high functional thin film transistor by suppressing aggregation of a molten semiconductor at the time of allowing strip-like pseudo-single crystals to continuously grow with a directional control by radiating beams to a semiconductor film made of silicon or the like using a continuous oscillation laser while scanning.

The present invention can obtain a system-in panel which incorporates a high functional thin film transistor therein, wherein a background film which is constituted of a silicon nitride film and a silicon oxide film is formed on an insulation substrate, and the silicon oxide film has the two-layered structure constituted of a silicon oxide film which is formed using SiH₄ and N₂O as raw material gases and a silicon oxide film which is formed using TEOS (Tetraethoxyorthosilicate) as a raw material gas thus suppressing aggregation.

In forming a top-gate type transistor, when a control of aggregation is emphasized, it is preferable to form the silicon oxide film A as an upper layer, while when the characteristic (mobility) of a thin film transistor is emphasized, it is preferable to form the silicon oxide film B as an upper layer. To describe the typical constitutions of the present invention, they are as follows.

A display device of the present invention includes an insulation substrate, a silicon nitride film formed on the insulation substrate, a silicon oxide film formed on the silicon nitride film, a semiconductor film formed on the silicon oxide film, and a thin film transistor which uses the semiconductor film.

Here, the silicon oxide film is constituted of a first silicon oxide film formed using SiH₄ and N₂O as raw material gases and a second silicon oxide film formed using a TEOS gas as a raw material gas, and the semiconductor film is made of pseudo-single crystal having strip-like grains.

Further, in a fabrication method of the above-mentioned display device of the present invention, the silicon oxide film is constituted of a first silicon oxide film formed using SiH₄ and N₂O as raw material gases and a second silicon oxide film formed using a TEOS gas as a raw material gas, and beams of continuous oscillation laser are radiated by scanning to the semiconductor film to melt and crystallize the semiconductor film thus reforming grains into a pseudo-single crystal having a strip-like grains.

By forming the silicon oxide film into the two-layered structure constituted of the silicon oxide film A and the silicon oxide film B without changing a total film thickness of the silicon oxide film, aggregation yield rate and the transistor characteristic can be controlled to obtain desired aggregation yield rate and a transistor characteristic thus achieving both suppression of aggregation and enhancement of the transistor characteristic whereby a high-definition system-in panel display device can be realized.

### BRIEF DESCRIPTION OF THE DRAWINGS

FIG. 1 is a view for explaining a mode of crystallization when a continuous oscillation laser is used;

FIG. 2A and FIG. 2B are views for explaining the generation of aggregation;

FIG. 3A and FIG. 3B are views for explaining generation states of aggregation depending on kinds of silicon oxide films;

FIG. 4 is a view for explaining the channel direction of strip-like crystal silicon in an active layer of a thin film transistor and the characteristic of a thin film transistor;

FIG. 5 is an explanatory view of a V_{G}-I_{D} characteristic of an N-channel single-drain thin film transistor which is produced using a silicon oxide film formed of a silicon oxide film A or a silicon oxide film B on a trial basis;

FIG. 6A and FIG. 6B are views for explaining an evaluation method of aggregation;

FIG. 7A to FIG. 7C are views for explaining field-effect mobility when the silicon oxide film has the two-layered structure constituted of a silicon oxide film A and a silicon oxide film B;

FIG. 8A and FIG. 8B are views showing a comparison result of field effect mobility and aggregation between the case in which the silicon oxide film which forms an upper layer is constituted of a silicon oxide film A and a case in which the silicon oxide film which forms the upper layer is constituted of the silicon oxide film B;

FIG. 9A to FIG. 9I are explanatory views of a fabrication process flow of top gate n-channel and p-channel TFTs to which the formation of silicon oxide film and the crystallization using the continuous oscillation laser are applied;

FIG. 10 is a cross-sectional view showing the completed structure of a C-MOS which is formed of an N-MOS single-drain TFT single body, a P-MOS LDD TFT single body or a combination of the above-mentioned N-MOS and P-MOS; and

FIG. 11 is a view for explaining one example of concentrations of nitrogen and carbon in the inside of the silicon oxide film.

### DESCRIPTION OF THE PREFERRED EMBODIMENTS

Hereinafter, embodiments of the present invention are explained in detail in conjunction with drawings showing the embodiments.

### Embodiment 1

In an embodiment 1, a following method which is obtained based on an actual experimental result is explained.

(1) When the silicon oxide film is formed of the two-layered structure, the silicon oxide film exhibits an aggregation suppression effect and a transistor characteristic which fall between an aggregation suppression effect and a transistor characteristic when a silicon oxide film A is formed of a single layer and an aggregation suppression effect and a transistor characteristic when a silicon oxide film B is formed of a single layer. Accordingly, by controlling film thicknesses of the silicon oxide film A and the silicon oxide film B, it is possible to control the suppression of aggregation and the transistor characteristic of the silicon oxide film.

(2) The characteristic of the silicon oxide film which is brought into contact with the silicon layer exhibits a larger effect. When the silicon oxide film A and the silicon oxide film B have the same film thickness, when the priority is assigned to the suppression of aggregation, the silicon oxide film A is selected as a film which is brought into contact with the silicon layer, while when the priority is assigned to the transistor characteristic, the silicon oxide film B is selected as the film which is brought into contact with the silicon layer.

(3) As described above, by arbitrarily selecting a kind of the film of an upper layer and a lower layer of the silicon oxide film or film thicknesses of the silicon oxide films A and B, it is possible to obtain a desired aggregation yield rate and a desired transistor characteristic.

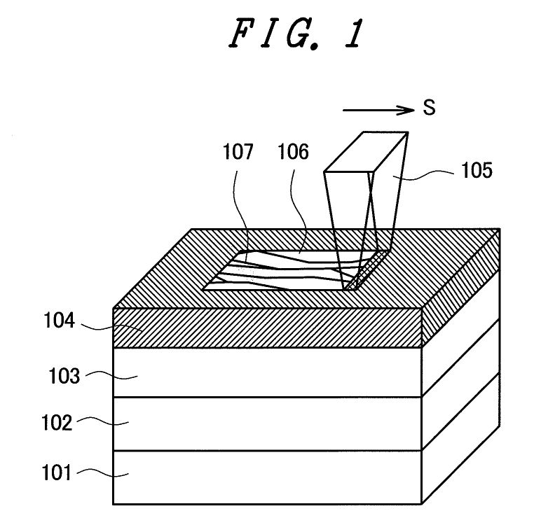

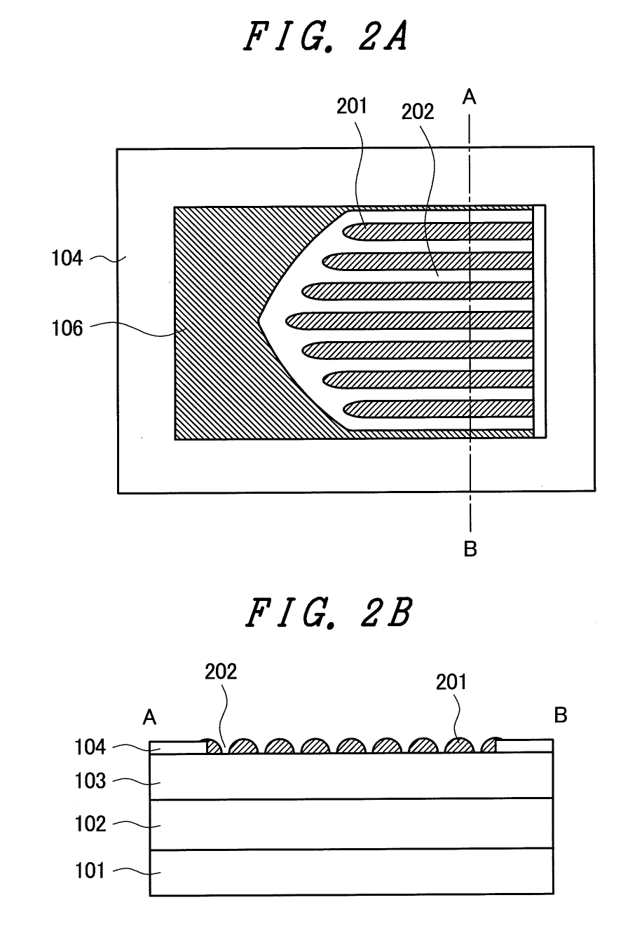

FIG. 1 is a view for explaining a mode of crystallization when a continuous oscillation laser is used. FIG. 2A and FIG. 2B are views for explaining the generation of aggregation, wherein FIG. 2A is a plan view, and FIG. 2B is a cross-sectional view taken along a line A-B in FIG. 2A. In FIG. 1, on a glass substrate 101, for preventing floating of Na impurities from glass, a silicon nitride film 102 and a silicon oxide film 103 are formed. A precursor silicon film 104 is formed on the silicon oxide film 103. The precursor silicon film may be formed of an amorphous silicon film or a poly silicon film formed by a CVD method or a crystallized film formed by an excimer laser.

Laser beams 105 of continuous oscillation are radiated to the precursor silicon film thus producing a flat silicon film 106 having crystals in the laser scanning direction S (strip-crystal silicon film, pseudo-single-crystal silicon film). This scanning implies that a laser radiation position and the precursor silicon film 104 perform the relative movement. That is, only the laser may be moved, only the substrate may be moved, or both laser and substrate may be moved. A grain boundary 107 is formed between the neighboring strip crystal silicon films 106.

Here, a laser stay time at one point on the silicon film becomes approximately several μs to several hundreds μs. A melting time of silicon is considered to be substantially equal to the laser stay time and hence, melting time is considerably long compared to a melting time when the film is formed by crystallization using the pulse laser. Accordingly, aggregation shown in FIG. 2A is generated thus forming portions 201 where the silicon layer is aggregated and portions 202 where the silicon layer is peeled off. Since the silicon layer is not present in the portions 202 where the silicon layer is peeled off, a transistor becomes inoperable thus lowering a fabrication yield rate of a display device. Here, symbol 106 indicates a pseudo-single crystal having strip-like grains.

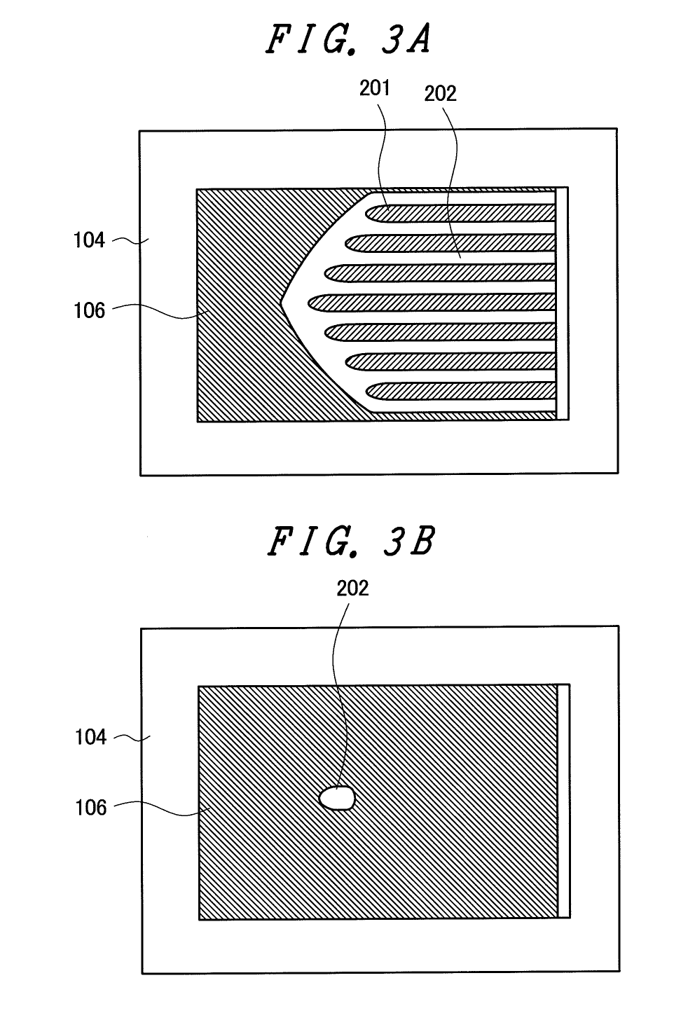

FIG. 3A and FIG. 3B are views for explaining generation states of aggregation depending on kinds of silicon oxide films. A film quality of the silicon oxide film 103 largely contributes to the suppression of aggregation and the transistor characteristic. FIG. 3A shows a state of aggregation when the silicon oxide film B is used as the silicon oxide film 103, and FIG. 3B shows a state of aggregation when the silicon oxide film A is used as the silicon oxide film 103. It is understood that the silicon oxide film A shown in FIG. 3B exhibits a small aggregation area and hence, the silicon oxide film A possesses a large aggregation suppression effect.

The grain boundary 107 of the strip-like crystal silicon layer which is crystallized by continuous oscillation laser shown in FIG. 1 is characterized in that the grain boundary 107 is arranged in the laser scanning direction S. Accordingly, in producing the thin film transistor, the transistor characteristic largely differs between a case in which the grain boundary direction and the source-drain direction are arranged parallel to each other and a case in which the grain boundary direction and the source-drain direction are arranged perpendicular to each other.

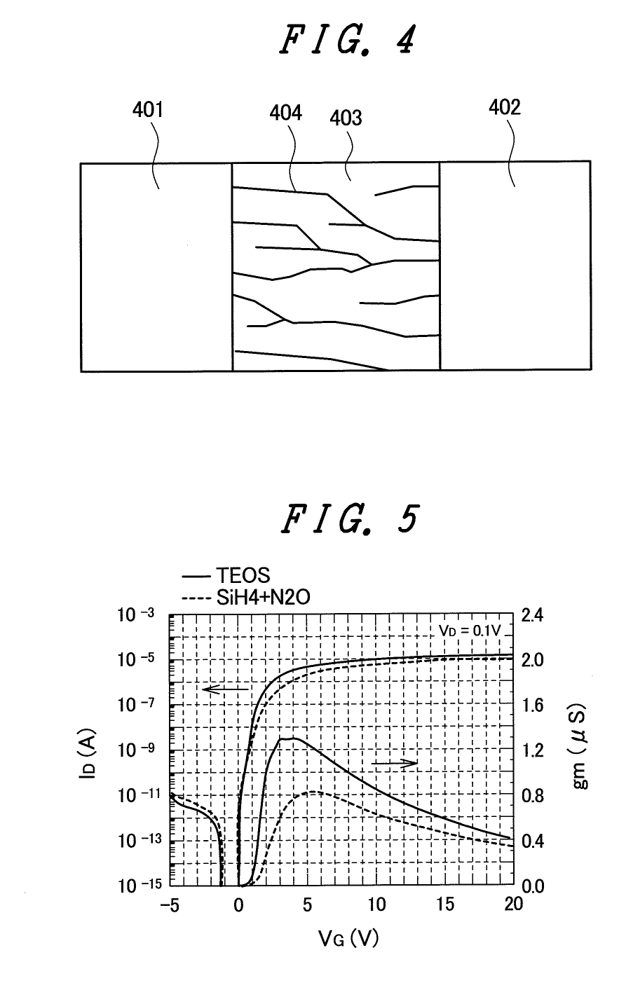

FIG. 4 is a view for explaining the channel direction of strip-like crystal silicon in an active layer of a thin film transistor and the characteristic of a thin film transistor. As shown in FIG. 4, by producing the thin film transistor such that the direction which connects the grain boundary and a source 401, a drain 402 (the carrier moving direction of a channel 403) becomes substantially parallel to the extending direction of a grain boundary 404 of the strip-like crystal silicon, the characteristic of the thin film transistor is largely enhanced.

FIG. 5 is an explanatory view of the V_{G}-I_{D} characteristic of an N-channel single-drain thin film transistor which is produced using a silicon oxide film 103 formed of a silicon oxide film A or a silicon oxide film B on atrial basis. A gate voltage V_{G}(V) is taken on an axis of abscissas, and a drain current I_{D}(A) and a mutual conductance gm (μs) are taken on an axis of ordinates. In FIG. 5, a solid line indicates the V_{G}-I_{D} characteristic of the silicon oxide film B formed using a TEOS gas, and a dotted line indicates the V_{G}-I_{D} characteristic of the silicon oxide film (silicon oxide film A) formed using SiH₄ and N₂O gases. As shown in FIG. 5, it is understood that the silicon oxide film B exhibits the favorable drain current I_{D}(A) and mutual conductance gm (μs) of the thin film transistor. Further, in this case, the silicon oxide film A exhibits field effect mobility of 240 (Vs/cm²) and the silicon oxide film B exhibits field effect mobility of 375 (Vs/cm²) and hence, the silicon oxide film B is superior to the silicon oxide film A with respect to field effect mobility.

Next, a method for obtaining desired aggregation and transistor characteristic which controls aggregation and transistor characteristic by forming the silicon oxide film into the two-layered structure constituted of the silicon oxide film A and the silicon oxide film B without changing a total film thickness of the silicon oxide film is explained.

First of all, an evaluation method of aggregation is explained. As an evaluation index of aggregation, “spread angle of aggregation” is used. FIG. 6A and FIG. 6B are views for explaining the evaluation method of aggregation. The spread angle of aggregation is an angle indicated by θ in FIG. 6A. With usual crystallization energy, there may be a sample in which aggregation does not spread as shown in FIG. 6B. The spread angle of aggregation is increased along with the increase of the crystallization energy. Accordingly, on a condition that the crystallization energy is increased so that all samples can obtain aggregation shown in FIG. 6A, the spread angles of aggregation are compared. A sample with a small spread angle of aggregation exhibits that a spread speed of a hole formed in molten silicon is slow and hence, the sample is hardly aggregated. With the usual energy, the smaller the spread angle of aggregation, both generation density of aggregation and size of an aggregation area become smaller and hence, the influence on a yield rate becomes small.

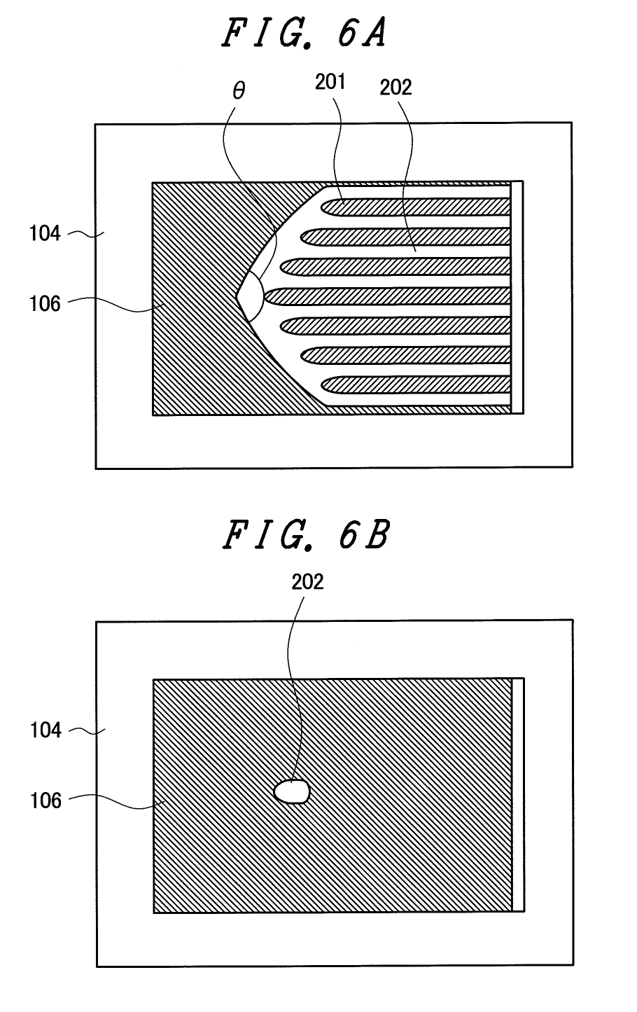

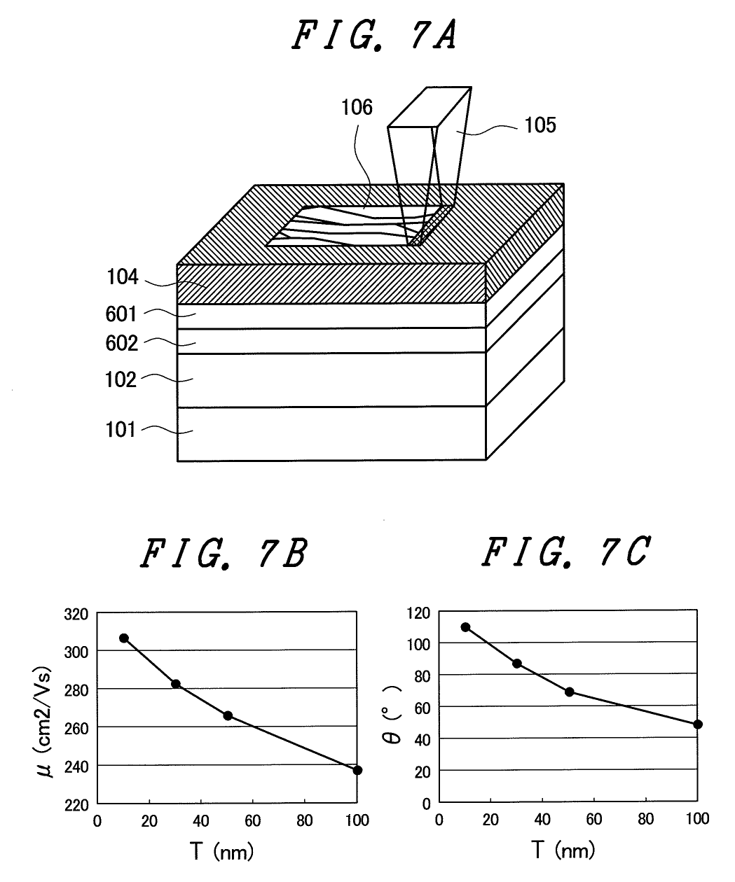

Next, a result of an actual experiment is explained. FIG. 7A to FIG. 7C are views for explaining field-effect mobility when the silicon oxide film has the two-layered structure constituted of the silicon oxide film A and the silicon oxide film B. As shown in FIG. 7A, the silicon oxide film which constitutes a background is formed such that an upper layer thereof is constituted of a silicon oxide film A601, and film thicknesses of the silicon oxide film A601 and a silicon oxide film B602 are respectively changed while setting a total film thickness of the silicon oxide film A and the silicon oxide film B to 100 nm. The aggregation and the transistor characteristic of the silicon oxide film in this case is shown in FIG. 7B and FIG. 7C. In FIG. 7B, the film thickness (nm) of the silicon oxide film A which constitutes the upper layer is taken on an axis of abscissas T, and field effect mobility (cm²/Vs) is taken on an axis of ordinates μ. Further, In FIG. 7C, the film thickness (nm) of the silicon oxide film A which constitutes the upper layer is taken on an axis of abscissas T, and a spread angle of aggregation (°) is taken on axis of ordinates θ.

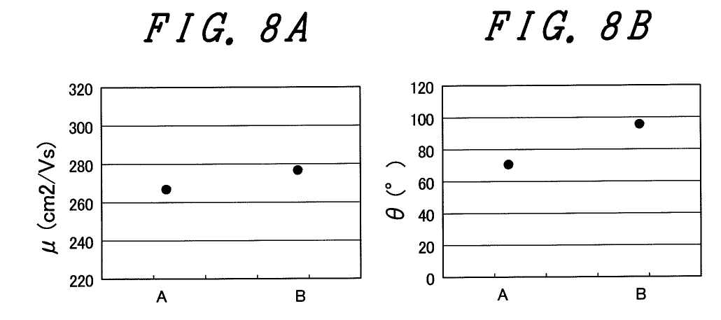

The field effect mobility μ is decreased along with the increase of the film thickness of the silicon oxide film A. On the other hand, the spread angle θ of aggregation becomes smaller along with the increase of the film thickness T of the silicon oxide film A. Further, a comparison result of field effect mobility and aggregation between a case in which the silicon oxide film constituting the upper layer is formed of a silicon oxide film A and a case in which the silicon oxide film constituting the upper layer is formed of the silicon oxide film B is shown in FIG. 8. In FIG. 8A, the silicon oxide film A and the silicon oxide film B which are formed as the upper layer are taken on an axis of abscissas, and field effect mobility (cm²/Vs) is taken on an axis of ordinates μ. Further, in FIG. 8B, the silicon oxide film A and the silicon oxide film B which are formed as the upper layer are taken on an axis of abscissas, and spread angle of aggregation (°) is taken on axis of ordinates θ.

The respective film thicknesses of the silicon oxide film A and the silicon oxide film B in FIG. 8A and FIG. 8B are 50 nm. As shown in FIG. 8A and FIG. 8B, when the upper layer is formed of the silicon oxide film A, the spread angle of aggregation is small (the aggregation suppression effect is increased) and field effect mobility is lowered. A trade-OFF relationship is established as a relationship between field effect mobility and aggregation.

Field effect mobility of 260 (cm²/Vs) or more is necessary. When it is also necessary to suppress aggregation as much as possible, for example, a thickness of the silicon oxide film A which constitutes the upper layer may be set to 60 nm and a thickness of the silicon oxide film B which constitutes a lower layer may be set to 40 nm. Further, the spread angle of aggregation of 80° or less is necessary. When it is also necessary to increase field effect mobility as much as possible, a thickness of the silicon oxide film A which constitutes the upper layer may be set to 40 nm, and a thickness of the silicon oxide film B which constitutes the lower layer may be set to 60 nm. Further, also when the silicon oxide film B constitutes the upper layer and the silicon oxide film A constitutes the lower layer, it is possible to determine film thicknesses using a similar technique.

Although not shown in the drawings, also when the silicon oxide film B is used as the upper layer, along with the increase of the film thickness of the silicon oxide film A, field effect mobility is decreased and the spread angle of aggregation is decreased (the aggregation suppression effect is increased) That is, although numerical values may change, the tendency substantially equal to the tendency shown in FIG. 7B and FIG. 7C is observed.

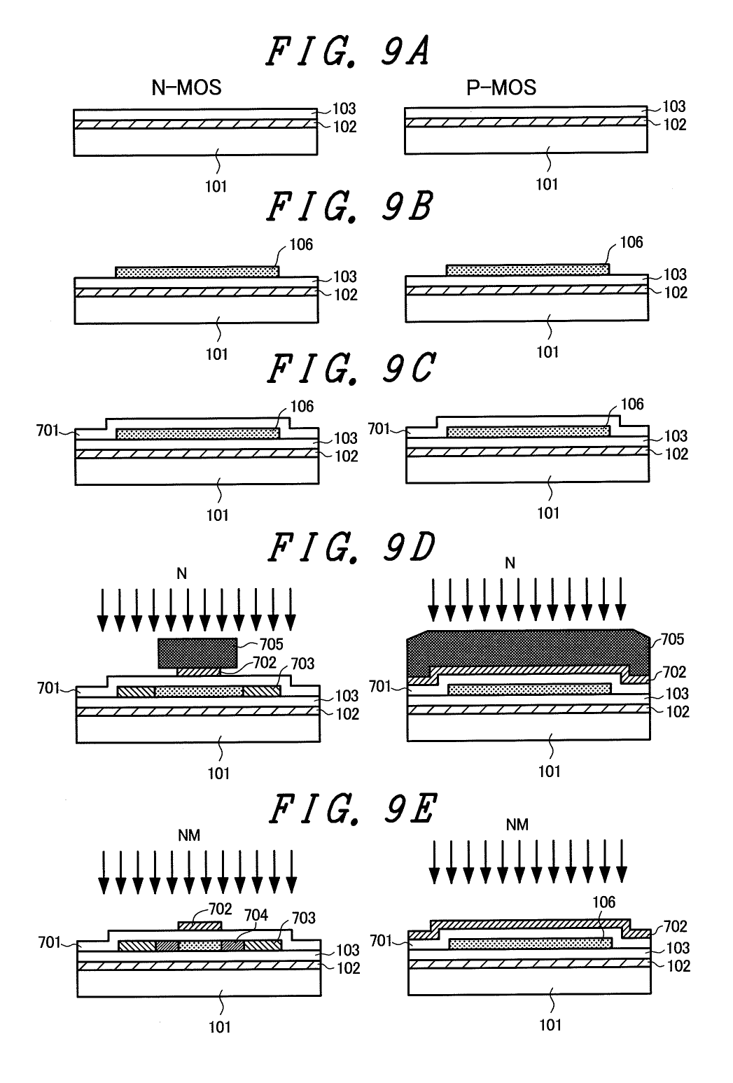

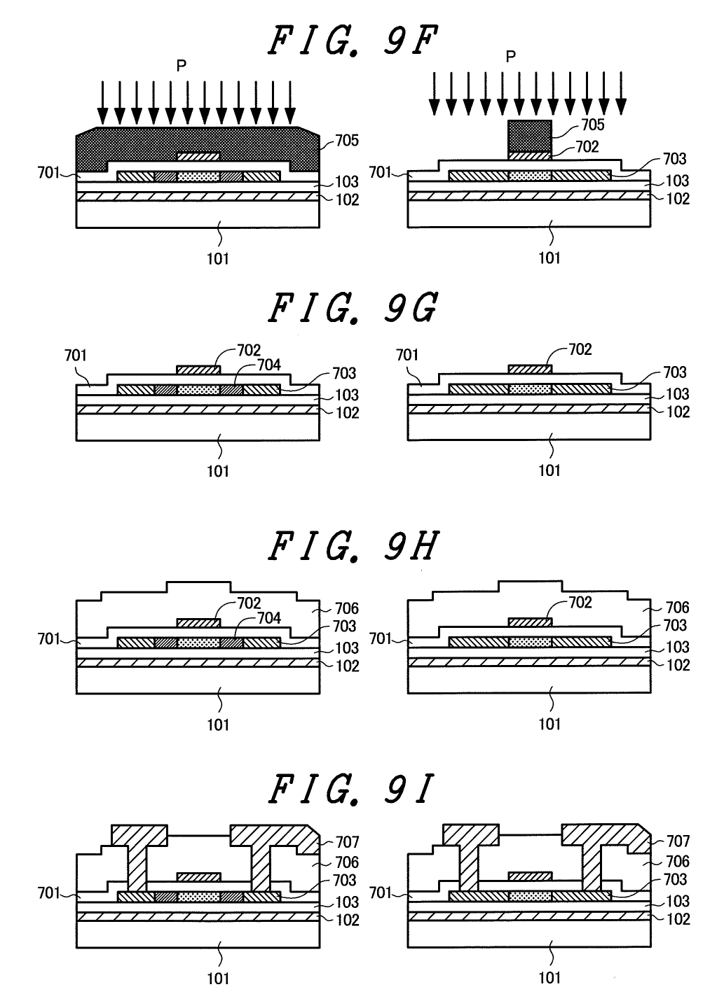

FIG. 9A to FIG. 9I are explanatory views of a fabrication process flow of top gate n-channel (N-MOS) and p-channel (P-MOS) TFTs to which the formation of silicon oxide film and the crystallization using the continuous oscillation laser are applied. In FIG. 9A to FIG. 9I, a left side shows the fabrication process of the N-MOS TFT in cross section and a right side shows a fabrication process of the P-MOS TFT in cross section.

First of all, on the glass substrate 101, the silicon nitride film 102 and the silicon oxide film 103 constituted of the silicon oxide film A and the silicon oxide film B for preventing floating of Na impurities from glass are formed (FIG. 9A) Further, an amorphous silicon film is formed on the silicon oxide film 103, and the pseudo-single-crystal silicon layer 106 is formed using the above-mentioned excimer laser anneal (ELA). device and the continuous oscillation laser. Thereafter, the pseudo-single-crystal silicon layer 106 is formed into an island shape by photo etching (FIG. 9B). A gate insulation film 701 is formed on the pseudo-single-crystal silicon layer (FIG. 9C)

As a self-aligning LDD layer forming process, after forming the gate electrode 702, only the NMOS TFT is etched with a depth of approximately 1 μm by side etching while leaving a resist 705. By performing the implantation of the high-concentration n-type impurities in such a state, a source-drain region 703 is formed on a poly-silicon layer. On the other hand, with respect to the PMOS TFT, a resist 705 is applied to the gate electrode 702 and hence, ions are not implanted into the poly-silicon layer (FIG. 9D).

After removing the resist, by implanting the low-concentration n-type impurities by way of the gate electrode 702 to which side etching is applied, the LDD (Lightly Doped Drain) region 704 of the concentration lower than the concentration of the source-drain region 703 is formed. On the other hand, with respect to the PMOS TFT, the source-drain region 703 is covered with the gate electrode 702 and hence, ions are not implanted into the poly-silicon layer (FIG. 9E).

Next, for forming the PMOS TFT, after applying the resist 705, only the PMOS TFT is etched to form the gate electrode 702. By performing the implantation of the high-concentration p-type impurities in such a state, the source-drain region 703 is formed on a poly-silicon layer. On the other hand, with respect to the NMOS TFT, the resist 705 is applied to the gate electrode 702 and hence, ions are not implanted into the poly-silicon layer (FIG. 9F). FIG. 9G shows cross sections of the NMOS TFT and the PMOS TFT before forming an interlayer film and lines.

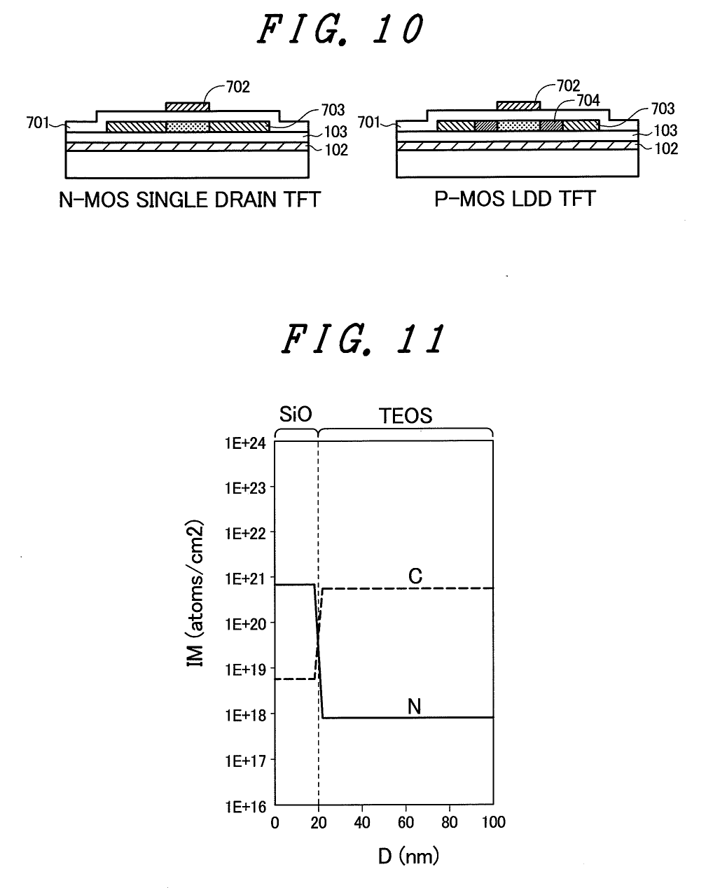

Further, after forming the interlayer insulation film 706 (FIG. 9H), contact holes leading to the source-drain region are formed by photo etching thus forming a source-drain electrode 707 (FIG. 9I). TFTs are formed in a pixel part and a circuit part by the above-mentioned method. The transistor circuit constitution includes a C-MOS which is formed of the N-MOS LDD TFT single body shown in FIG. 9G, the P-MOS single drain TFT single body, the N-MOS single drain TFT single body whose completed structure is shown in FIG. 10, the P-MOS LDD TFT single body, or the combination of the NMOS TFT and the PMOS TFT.

The silicon oxide film 103 fabricated by the above-mentioned method has following features. Since the silicon oxide film is formed as the film having two-layered structure constituted of the silicon oxide film A and the silicon oxide film B, the silicon oxide film 103 is characterized by the concentrations of nitrogen and carbon in the inside of the silicon oxide film. FIG. 11 is a view for explaining one example of concentrations of nitrogen and carbon in the inside of the silicon oxide film. A depth D (nm) from a surface of the silicon oxide film is taken on an axis of abscissas and impurity concentration IM (atoms/cm²) is taken on an axis of ordinates. SiO is an upper-layer silicon oxide film A (SiO film). TEOS is a lower-layer silicon oxide film B (TEOS film). FIG. 11 shows a result of measurement of concentrations of nitrogen and carbon in a sample formed of the silicon oxide film B having a thickness of 80 nm and the silicon oxide film A having a thickness of 20 nm using SIMS which can measure the concentration in the depth direction. The silicon oxide film 103 is also characterized in that the carbon concentration C in the silicon oxide film B is 1E+20 (atoms/cm²), and the nitrogen concentration N in the silicon oxide film A is 1E+20 (atoms/cm²) or more. The silicon oxide film is not limited to the two-layered structure constituted of the silicon oxide film A and the silicon oxide film B and may be formed of the three-or-more-layered structure.

Although the present invention has been explained with respect to the case in which the semiconductor which constitutes the thin film transistor is formed of the silicon semiconductor, the semiconductor which constitutes the thin film transistor is not limited to the silicon semiconductor and may be formed of other semiconductor.

What is claimed is:

1. A display device comprising:
an insulation substrate;
a silicon nitride film formed on the insulation substrate;
a silicon oxide film formed on the silicon nitride film;
a semiconductor film formed on the silicon oxide film; and
a thin film transistor which uses the semiconductor film, wherein
the silicon oxide film includes a first silicon oxide film formed using SiH₄ and N₂O as raw material gases and a second silicon oxide film formed using a TEOS gas as a raw material gas, and
the semiconductor film is made of pseudo-single crystal having strip-like grains.

2. A fabrication method of a display device which includes an insulation substrate, a silicon nitride film formed on the insulation substrate, a silicon oxide film formed on the silicon nitride film, a semiconductor film formed on the silicon oxide film, and a thin film transistor which uses the semiconductor film, wherein
the silicon oxide film is constituted of a first silicon oxide film formed using SiH₄ and N₂O as raw material gases and a second silicon oxide film formed using a TEOS gas as a raw material gas, and
beams of continuous oscillation laser are radiated by scanning to the semiconductor film to melt and crystallize the semiconductor film thus reforming grains into a pseudo-single crystal having a strip-like grains.
